(19) United States
(12) Patent Application Publication
(10) Pub. No.: US 2026/0006822 A1
(43) Pub. Date: Jan. 1, 2026

(54) Field-Effect Transistor Device Having Blocking Region

(71) Applicant: Soochow University, Suzhou City, Jiangsu Province (CN)

(72) Inventors: Mingxiang Wang, Suzhou City (CN); Min Liu, Suzhou City (CN); Guoao Zhou, Suzhou City (CN); Dongli Zhang, Suzhou City (CN); Huaisheng Wang, Suzhou City (CN)

(21) Appl. No.: 18/881,416

(22) PCT Filed: Oct. 27, 2022
(86) PCT No.: PCT/CN2022/127849

§ 371 Date: Jan. 6, 2025

(30) Foreign Application Priority Data
Jul. 26, 2022 (CN) 202210887598.5

(51) Int. Cl. H10D 30/47

(52) U.S. Cl. CPC H10D 30/475

(57) ABSTRACT

The present invention discloses a field-effect transistor device having a blocking region, for use in solving the problem of short-channel effects of field-effect transistors in the prior art. The field-effect transistor device includes an active layer, and the active layer includes a source region, a drain region, and a channel region located between the source region and the drain region. When the device is switched on, an effective channel and an equivalent source region and an equivalent drain region that are distant from the effective channel at least in the thickness direction of the channel region are formed in the channel region, and the field-effect transistor device supplies an working current by connecting the source region and the drain region by means of the effective channel, the equivalent source region, and the equivalent drain region; the field-effect transistor further includes a carrier blocking region, and in a plane perpendicular to the length direction of the effective channel, the vertical projections of the equivalent source region and the equivalent drain region are located in the vertical projection of the carrier blocking region.

The present invention claims priority to Chinese Patent Invention No. 2022108875985, entitled “FIELD-EFFECT TRANSISTOR DEVICE HAVING BLOCKING REGION”, filed on Jul. 26, 2022 to the Chinese Patent Office, which is incorporated herein by reference in its entirety.

### TECHNICAL FIELD

The present invention relates to a technical field of semiconductor devices, and specifically relates to a field-effect transistor device having a blocking region.

### BACKGROUND ART

With the development of integrated circuit technology, the gate length (corresponding to the channel length) of field-effect transistors shrinks, and VLSI chips based on sub-micron or even less than 10 nm technology node devices have been mass-produced. For such small-size devices, it is an important challenge in device technology on how to cope with the short-channel effects. The threshold voltage and subthreshold characteristics of small-size devices are all degraded by short-channel effects, which shows that the threshold voltage of the device is no longer a constant, but decreases with the decrease of channel length and the increase of drain terminal voltage of the device. Subthreshold swing in device transfer characteristics also degrades simultaneously.

In order to improve short-channel effects of field-effect transistor devices, current architectures mainly include fin field-effect transistor (FinFET), silicon-on insulator (SOI), lightly-doped drain (LDD) structure and a metal source/drain Schottky barrier transistor (SB MOSFET). The channel region of FinFET is a 3D fin-type slice, and the gate electrode is a three-sided surrounding gate structure. The two side gates enhance the control of the gate electrode on the channel and effectively suppress short-channel effects. The preparation process of the device in this scheme is much more complex than that of the planar device. At present, chips below the 22 nm technology node widely adopt FinFET scheme. The SOI technology introduces a buried oxide layer between the silicon channel layer and the bulk substrate, which may effectively suppress the leakage current between the source and drain under the condition that the channel layer is very thin and fully depleted. The difficulty of this scheme lies in the very high cost of SOI silicon wafers. At present, chips based on the 10-nm technology node of the SOI scheme have been mass-produced. The lightly-doped drain (LDD) is arranged near the drain channel while the source and drain regions far away from the channel are still heavily doped. The drain PN junction formed by the lightly-doped region reduces the influence of the drain voltage on the channel, and is a mainstream technical solution in which the on-state current and field-effect mobility of the device are both reduced to a certain extent by the influence of the LDD. The on-state current of Schottky barrier transistor is mainly determined by the tunneling current through the Schottky barrier between metal source electrode and semiconductor channel, which is not sensitive to short-channel effects. The scheme is difficult to process, and the choice of barrier material is limited, and it is difficult to balance the suppression of the off-state current.

On the other hand, the kink effect on the output characteristic curve of the short-channel device has also received much attention. When the device works in the saturation regime, the higher drain voltage makes the drain of the device deplete and forms a high electric field region, where the carrier is prone to impact ionization effect, and couples with the parasitic bipolar transistor of MOS device to amplify, so that the drain current increases rapidly with the increase of drain voltage, forming the so-called kink current, the output characteristic curve of the device greatly warps, seriously affecting the normal output characteristics.

Common methods for improving the kink effect mainly include increasing the channel length and lightly-doped drain (LDD) structure of the device. Increasing the channel length may reduce the impact of carriers generated by impact ionization at the drain terminal, weaken the parasitic transistor effect and mitigate the kink effect. However, an increase in channel length will correspondingly decrease the output current of the device. The LDD structure may reduce the peak electric field intensity in the depletion region at the drain and weaken the carrier impact ionization effect, thus suppressing the kink effect. However, the LDD structure may introduce additional parasitic resistance and reduce the field-effect mobility and on-state current of the device.

### SUMMARY OF THE INVENTION

An objective of the present invention to provide a field-effect transistor device for solving the problem of short-channel effects of field-effect transistors in the prior art.

In order to achieve the above-mentioned objective, the present invention provides a field-effect transistor device having a blocking region including an active layer. The active layer includes a source region, a drain region, and a channel region located between the source region and the drain region. When the device is in an on-state, an effective channel and an equivalent source region and/or an equivalent drain region that are distant from the effective channel at least in a thickness direction of the channel region are formed in the channel region, and the field-effect transistor device supplies a working current by connecting the source region and the drain region by means of the effective channel, and the equivalent source region and/or the equivalent drain region.

The field-effect transistor further includes a carrier blocking region, and in a plane perpendicular to the length direction of the effective channel, vertical projections of the equivalent source region and of the equivalent drain region are located within a vertical projection of the carrier blocking region.

In one embodiment, a conductive region without connecting the source region and the drain region is formed in the channel region. When the conductive region is connected with the source region, the conductive region constitutes the equivalent source region; and/or, when the conductive region is connected with the drain region, the conductive region constitutes the equivalent drain region.

In one embodiment, a first gate electrode arranged on a side surface of the active layer is included. A vertical projection of the first gate electrode on the channel region overlaps with a vertical projection of the conductive region on the channel region. The first gate electrode is capable of controlling the channel region and forming a channel therein, and a portion of the channel that does not overlap with the vertical projection of the conductive region on the channel region constitutes the effective channel.

In one embodiment, when the device is in an on-state, a conductance of the conductive region is greater than a conductance of a remainder of the channel excluding the effective channel, so that at least one of the conductive region and the effective channel is capable of injecting carriers into the other of the conductive region and the effective channel.

In one embodiment, the conductance of the conductive region is at least three times greater than the conductance of the remainder of the channel excluding the effective channel.

In one embodiment, the field-effect transistor device is a planar structure device or a vertical structure device.

In one embodiment, when the device is in an on-state, a conductance per unit length of an effective channel in the channels is less than a conductance per unit length of a remainder of the channel excluding the effective channel.

In one embodiment, the field-effect transistor device includes a gate insulating layer arranged between the first gate electrode and a channel region, where thickness of a portion of the gate insulating layer corresponding to the effective channel is greater than that of the remainder of the gate insulating layer.

In one embodiment, the field-effect transistor device includes a gate insulating layer arranged between the first gate electrode and a channel region, where a dielectric constant of a portion of the gate insulating layer corresponding to the effective channel is greater than that of the remainder of the gate insulating layer.

In one embodiment, when the field-effect transistor device is an N-type device, a work function of a portion of the first gate electrode corresponding to the effective channel is greater than a work function of the remainder of the first gate electrode; and when the field-effect transistor device is a P-type device, a work function of a portion of the first gate electrode corresponding to the effective channel is less than a work function of the remainder of the first gate electrode.

In one embodiment, a contact interface of the carrier blocking region and the channel region forms a potential energy barrier for preventing carriers from entering the carrier blocking region.

In one embodiment, the carrier blocking region is an insulating region or a semi-insulating region.

In one embodiment, the dielectric constant of the carrier blocking region is less than the dielectric constant of the channel region.

In one embodiment, vertical projections of the carrier blocking region and the equivalent source region and/or the equivalent drain region on the channel region do not overlap.

In one embodiment, the carrier blocking region is in contact with one terminal of the equivalent source region away from the source region.

In one embodiment, the carrier blocking region is in contact with one terminal of the equivalent drain region away from the drain region.

In one embodiment, the carrier blocking region is a dielectric material filled in the trenches of the channel region.

In one embodiment, the carrier blocking region is an insulating region or a semi-insulating region formed by ion implantation or doping in the channel region.

In one embodiment, the carrier blocking region is a dielectric material formed on a substrate, and the active layer is prepared on the substrate on which the dielectric material is formed.

In one embodiment, a second gate electrode arranged on a side surface of the active layer adjacent to the conductive region is further included, where the second gate electrode can control the formation of the conductive region in the channel region.

In one embodiment, the conductive region is formed by doping the introduced carriers by the channel region on a side surface away from the effective channel.

In one embodiment, an insulating layer is further provided on a surface of the active layer on a side away from the effective channel, where the conductive region is composed of carriers generated in the channel region adjacent to the insulating layer by the injected charges in the insulating layer through electrostatic induction.

In one embodiment, a semiconductor material layer provided on a side surface of the active layer away from the effective channel is further included, where the active layer and the semiconductor material layer form a heterostructure, the conductive region is constituted by a two-dimensional electron gas channel or a two-dimensional hole gas channel distributed in the heterostructure.

In one embodiment, the conductive region is constituted by a two-dimensional electron gas channel or a two-dimensional hole gas channel formed by surface treatment of a side surface of the channel region away from the effective channel.

Compared with the prior art, in the embodiments of the present invention, when the device is in an on-state, an effective channel can be formed in a channel region, and an equivalent source region and an equivalent drain region of the channel region are far away from the effective channel in the thickness direction, so that the field-effect transistor device supplies a working current by connecting the source region and the drain region; as such, the equivalent drain (source) region connected with the drain (source) electrode is structurally far away from the effective channel, so that the influence of the drain voltage on the effective channel can be reduced. Furthermore, the peak electric field in the depletion region of the drain is reduced when the device is in saturation operation, thus the short-channel effect of the device is suppressed and the output characteristic of the device is improved. At the same time, by arranging the carrier blocking region so that, in a plane perpendicular to the length direction of the effective channel, vertical projections of the equivalent source region and the equivalent drain region are located in the vertical projection of the carrier blocking region, carriers can be blocked from being directly injected into the equivalent drain region from the equivalent source region, thereby reducing the off-state current of the device.

### BRIEF DESCRIPTION OF THE DRAWINGS

FIG. 1 is a schematic diagram showing an equivalent source region, an equivalent drain region and an effective channel are formed when a field-effect transistor device having a blocking region according to an embodiment of the present invention is in an on-state;

FIG. 2 is a schematic structural diagram showing a field-effect transistor device having a blocking region in an on-state according to an embodiment of the present invention;

FIG. 3 is a schematic diagram showing a conductive region is formed in a field-effect transistor device having a blocking region according to an embodiment of the present invention;

FIGS. 4-9 are schematic structural diagrams showing a field-effect transistor device having a blocking region according to various embodiments of the present invention;

FIGS. 10 to 17 are schematic diagrams showing the manufacture of a conductive region in various embodiments of the present invention;

FIGS. 18 to 20 are schematic structural diagrams showing a SOI device to which the scheme of the present invention is applied;

FIG. 21 is a schematic structural diagram showing an effective channel of a field-effect transistor device having a blocking region and a conductive region having a spacing between vertical projections of the conductive region on the channel region according to one embodiment of the present invention;

FIG. 22 is a graph comparing transfer characteristics of different devices in simulation embodiment 1 according to the present invention;

FIG. 23 is a graph comparing output characteristics of different devices in simulation embodiment 1 according to the present invention;

FIG. 24 is a graph comparing transfer characteristics of different devices in simulation embodiment 2 according to the present invention;

FIG. 25 is a graph comparing output characteristics of different devices in simulation embodiment 2 according to the present invention;

FIG. 26 is a graph comparing transfer characteristics of different devices in simulation embodiment 3 according to the present invention;

FIG. 27 is a graph comparing output characteristics of different devices in simulation embodiment 3 according to the present invention;

FIG. 28 is a graph comparing transfer characteristics of different devices in simulation embodiment 4 according to the present invention;

FIG. 29 is a graph comparing output characteristics of different devices in simulation embodiment 4 according to the present invention;

FIG. 30 is a graph comparing transfer characteristics of different devices in simulation embodiment 5 according to the present invention; and

FIG. 31 is a graph comparing output characteristics of different devices in simulation embodiment 5 according to the present invention.

### DETAILED DESCRIPTION OF THE INVENTION

Exemplary embodiments that show features and advantages of the present invention are described in detail below. It is understood that the present invention can vary in different embodiments without departing from the scope of the present invention, and that the description and drawings are to be taken as illustrative and not restrictive in any aspect.

Unless defined otherwise, all technical and scientific terms used herein have the same meaning as commonly understood by a person skilled in the art to which the present invention belongs. The terminology used in the description of the present invention herein is for the purpose of describing embodiments only and is not intended to be limiting of the present invention.

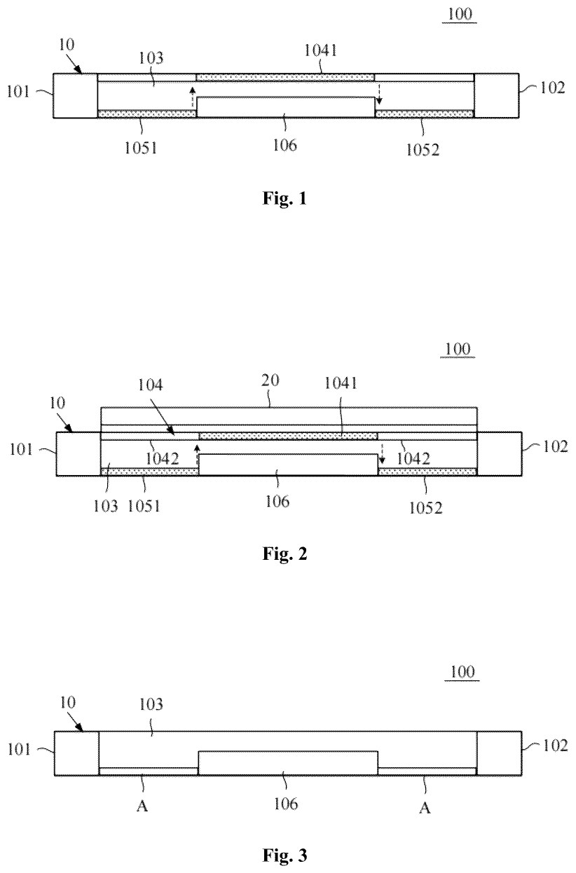

Referring to FIG. 1, an embodiment of a field-effect transistor device having a blocking region of the present invention is described. In the present embodiment, the field-effect transistor device 100 comprises an active layer 10 which includes a source region 101, a drain region 102, and a channel region 103. A source region 101 and a drain region 102 are located on two sides of the active layer 10 respectively, and a channel region 103 is located between the source region 101 and the drain region 102. In conjunction with the schematic view shown in FIG. 1, when the device is at on-state, an effective channel 1041, an equivalent source region 1051 and an equivalent drain region 1052 away from the effective channel 1041 in the thickness direction of the channel region 103 are formed in the channel region 103 of the field-effect transistor, and the field-effect transistor device 100 contributes a working current by connecting the source region 101 with the drain region 102 via the effective channel 1041, the equivalent source region 1051 and the equivalent drain region 1052.

In some embodiments of the present invention, the equivalent source region 1051 and equivalent drain region 1052 can also be away from the effective channel 1041 in a length direction of the channel region, in addition to the thickness direction of the channel region. In these embodiments, the expression of “away from” in either the thickness or length direction of the channel region is defined as long as the effective channel 1041, the equivalent source region 1051, and the equivalent drain region 1052 can connect the source region 101 with the drain region 102 when the device is in an on-state.

In a typical field-effect transistor device 100, the source region 101 in the active layer 10 is used to provide carriers when the device is at on-state, and the drain region 102 is used to collect carriers provided by the source region 101. Correspondingly, in the present invention, the equivalent source region 1051 refers to a structure in which a portion of carriers provided by the source region 101 are directly injected into the effective channel 1041, and the equivalent drain region 1052 refers to a structure in which a portion of carriers are directly received from the effective channel 1041 and injected into the drain region 102.

In conjunction with referring to FIG. 2, the term “effective channel 1041” as mentioned in this invention refers to a portion of the channel through which the carriers serving as the working current will pass when the device is at on-state. Taking this embodiment as an example, one side surface of the active layer 10 may be arranged with a first gate electrode 20, and there is no spacing between the vertical projection of the first gate electrode 20 on the active layer 10, and the source region 101 and the drain region 102. Thus, when a gate voltage is applied to the first gate electrode 20 to turn the device on, a channel 104 may be controllably formed beneath the first gate electrode 20 and structurally connected to the source region 101 and the drain region 102 correspondingly. From a functional point of view, however, only the portion of the channel that does not overlap the vertical projection of the equivalent source region 1051 and the equivalent drain region 1052 on the channel region 103 is used to transfer the full working current, and therefore only this portion of the channel will be referred to herein as the “effective channel 1041”.

In this embodiment, when the device is in an on-state, the carrier path includes two main portions: one portion enters the equivalent source region 1051, the effective channel 1041, the equivalent drain region 1052 and the drain region 102 in sequence from the source region 101, and the other portion enters the drain region 102 directly through the channel 104 from the source region 101. The remaining portion of the channel 104 except for the effective channel 1041 is used to transfer only a portion of the working current as viewed from the carrier path.

It may be seen that the effective channel 1041 in this invention does not limit itself to having a different device structure or parameter setting than the rest portion of the channel 104. Indeed, in some embodiments, the channel 104 described above may be integrally formed in the channel region, and only by the arrangement of the equivalent source region 1051 and the equivalent drain region 1052, the carriers provided by the source region 101 are not injected directly into the drain region 102 all through the channel 104 when the device is on. However, the regulation of the channel, such as changing the work function of the first gate electrode corresponding to the effective channel, the thickness of the gate insulating layer, etc. which may be shown in some embodiments below, should not be considered as necessary preconditions for forming the effective channel.

The arrangement of the equivalent source region 1051 and the equivalent drain region 1052 is equivalent to shortening the length of the portion of the channel 104 which may fully conduct the working current, namely, creating a spacing between the effective channel 1041 and the source region 101, and between the effective channel 1041 and the drain region 102. In addition, the equivalent drain region 1052 connected with the drain region 102 is structurally away from the effective channel 1041, reducing the influence of the drain potential on the effective channel 1041; while the equivalent source region 1051 connected with the source region 101 is structurally away from the effective channel 1041, the potential of the equivalent source region 1051 remains the same as that of the source region (usually a zero potential), also reduces the influence of the drain potential on the effective channel 1041, so as to improve the short-channel effects of the device.

Referring to FIG. 3, in the specific preparation of the equivalent source region 1051 and the equivalent drain region 1052, a conductive region A which is not connected to the source region 101 and the drain region 102 can be formed in the channel region 103. When the conductive region A is connected to the source region 101, this part of the conductive region A constitutes the equivalent source region 1051. When the conductive region A is connected with the drain region 102, this portion of the conductive region A constitutes the equivalent drain region 1052.

When the device is in an on-state, the conductance of conductive region A is set to be greater than that of the remainder 1042 of the channel 104 excluding the effective channel 1041 so that carriers can be injected into each other between the conductive region A and the effective channel 1041. As such, the carriers in the source region 101 are attracted by the equivalent source region 1051 with more conductance, and not be directly injected into the remainder 1042 of the channel 104 which is directly connected to the source region 101; similarly, carriers transporting in the effective channel 1041 are also be attracted by the equivalent drain region 1052, rather than transporting entirely by means of the remainder 1042 of the channel 104.

To achieve the carrier injection arrangement herein between the equivalent source region 1051, the equivalent drain region 1052, and the effective channel 1041, the conductance of the conductive region A may be arranged to be at least three times greater than the conductance of the remainder 1042 of the channel 104 excluding the effective channel 1041. Also, since carriers flow in the thickness direction of the channel region 103 during the above-mentioned “injection”, the spacing between the conductive region A and the effective channel 1041 in the thickness direction of the channel region 103 in the present embodiment may be set to 5 nm to 10 μm, or more preferably 10 nm to 1 μm, or more preferably 10 nm to 100 nm according to the specific design of different devices, to ensure the normal injection of the carriers and the performance of the devices.

It should be noted that “carriers” mentioned in the present invention refers to charge particles that are free to move in the respective polar channel/conductive region A. Generally, the electrons in the N-type channel or holes in the P-type channel are referred as “carriers” herein, and accordingly, holes in the N-type channel or electrons in the P-type channel are not referred as “carriers”. Therefore, the polarities of the effective channel 1041 and the conductive region A are set to be the same in the present invention, so that the carrier interaction between the two channels can ultimately contribute substantially to the working current of the device.

It can be seen that when the device is in an off-state, for example, the channel 104 can be controlled to be switched off by the first gate electrode 20, at which time the effective channel 1041 also “disappears” accordingly. In these embodiments, the equivalent source region 1051 and the equivalent drain region 1052 may not disappear as the effective channel 1041 disappears, i.e., the equivalent source region 1051 and the equivalent drain region 1052 may still be present in the channel region 103 when the device is in an off-state. At this time, an unexpected result is that: carriers are injected directly into the equivalent drain region 1052 via the equivalent source region 1051, resulting in an increase in the off-state current of the device.

To address the above challenge, in the present embodiment, the field-effect transistor device 100 further includes a carrier blocking region 106. In a plane perpendicular to the length of the effective channel 1041, the vertical projections of the equivalent source region 1051 and the equivalent drain region 1052 lie within the vertical projection of carrier blocking region 106.

The carrier blocking region 106 may functionally block the passage of the carriers in the channel region 103. Since the possible movement of the carriers between the equivalent source region 1051 and the equivalent drain region 1052 as a whole follows the principle of “shortest path” when the device is in an off-state, projections of the equivalent source region 1051 and the equivalent drain region 1052 on a plane perpendicular to the effective channel 1041 are both within the projection of the carrier blocking region 106 on that plane, which essentially causes the carrier blocking region 106 to “block” the shortest path for the carriers to be injected from the equivalent source region 1051 into the equivalent drain region 1052.

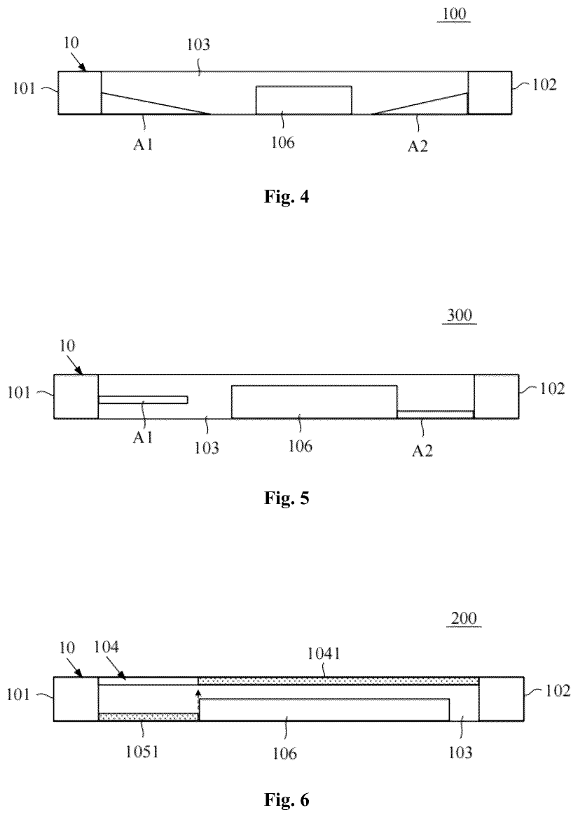

In various embodiments, the morphology and location of the conductive region A may be set according to the requirements of the device and are not limited to the configuration shown in FIG. 3. For example, the conductive region A in the field-effect transistor device 100 shown in FIG. 4 may have a greater overall thickness and irregular area shape relative to FIG. 3. As another example, the conductive region A in the field-effect transistor device 100 shown in FIG. 5 is not located at the same height in the thickness direction of the channel region. In the embodiment of either FIG. 3 or FIG. 4, since vertical projections of the equivalent source region and the equivalent drain region formed by the conductive region A are located within the vertical projection of the carrier blocking region 106 in a plane perpendicular to the effective channel length direction, carriers can be blocked from being directly injected into the equivalent drain region from the equivalent source region, thereby reducing the off-state current of the device.

Referring to FIGS. 3-5, in the embodiment of FIG. 3, the carrier blocking region 106 is in contact with one end of the equivalent source region that is away from the source region, and is in contact with one end of the equivalent drain region away from the drain region. In the embodiment of FIG. 4, the carrier blocking region 106 is not in contact with neither the equivalent source region nor the equivalent drain region. In the embodiment of FIG. 5, the carrier blocking region 106 contacts only the end of the equivalent drain region that is away from the drain region. That is to say, the carrier blocking region does not need to be limited in structural contact with the equivalent source region or the equivalent drain region, but only needs to be capable of blocking direct injection of carriers from the equivalent source region into the equivalent drain region.

The carrier blocking region 106 may be implemented based on various principles. For example, (1) the carrier blocking region 106 may form a potential energy barrier at its interface with the channel region, thereby preventing the migration of the carriers; (2) the carrier blocking region 106 itself has an insulating or semi-insulating property to prevent carriers from moving within itself; (3) the carrier blocking region 106 has a low dielectric constant, so that the electric field around it is weakened, thereby weakening the movement of the carriers.

Based on the above principles, the carrier blocking region 106 can be prepared in a variety of ways.

In one embodiment, a trench may be formed in the channel region by etching etc., and a dielectric material may be filled in the trench to prepare the carrier blocking region 106. The dielectric material may be a material having a dielectric constant lower than that of the channel region, an insulating or semi-insulating material, a dielectric material capable of forming a potential energy barrier blocking the passage of carriers at an interface with the channel region, or any suitable material having a combination of the above properties. Illustratively, the dielectric material filled therein may be a low dielectric constant dielectric material such as semi-insulating GaAs filled by a process such as deposition etc., or alternatively, may be directly filled with an air atmosphere, an inert gas atmosphere, or a vacuum.

In one embodiment, an insulating or semi-insulating region may be formed by injecting F, O, N, Co, etc. in the channel region by ion implantation or doping to prepare this carrier blocking region 106.

In one embodiment, a carrier blocking region 106 of a suitable dielectric material may also be formed on a substrate by processes such as deposition and etching, and then an active region of the device may be formed on the substrate on which the carrier blocking region 106 has been formed, thereby completing the fabrication of the entire field-effect transistor device. Similarly, the dielectric material may be a material having a dielectric constant lower than that of the channel region, an insulating or semi-insulating material, a dielectric material capable of forming a potential energy barrier to the passage of carriers at an interface with the channel region, or any suitable material having a combination of the above properties, which will not be described in detail herein.

Referring to FIG. 6, yet another embodiment of a field-effect transistor device 200 of the present invention is described.

Unlike the embodiments described above, in the present embodiment, no equivalent drain region is formed in the channel region 103 at this time when the device is in an on-state. The field-effect transistor device 200 supplies a working current by connecting the source region 101 and the drain region 102 by means of an effective channel 1041 and an equivalent source region 1051.

In the present embodiment, it is equivalent to reducing the influence of the drain potential on the potential near the source of the channel region 103 only by the arrangement of the equivalent source region 1051, thereby improving the short-channel effect of the device. Correspondingly, the effective channel 1041 is directly connected to the drain region 102.

When the device is in an on-state, during carrier transport process, carriers provided by the source region 101 partially enter the equivalent source region 1051, and are injected into the effective channel 1041 from one end of the equivalent source region 1051 that is away from the source region 101. The carriers flowing through the effective channel 1041 are re-injected back into the drain region 102. That is, in the present embodiment, only the conductive region injects carriers unidirectionally into the effective channel 1041.

Correspondingly, in the present embodiment, the vertical projection of the equivalent source region 1051 lies within the vertical projection of the carrier blocking region 106 in a plane perpendicular to the length direction of the effective channel 1041. In such an embodiment, since an equivalent drain region is not provided, it is the carrier blocking region 106 that “blocks” the shortest path in the equivalent source region 1051 for which carriers are directly injected into the drain region 102, thereby also serving the function of reducing the off-state current of the device.

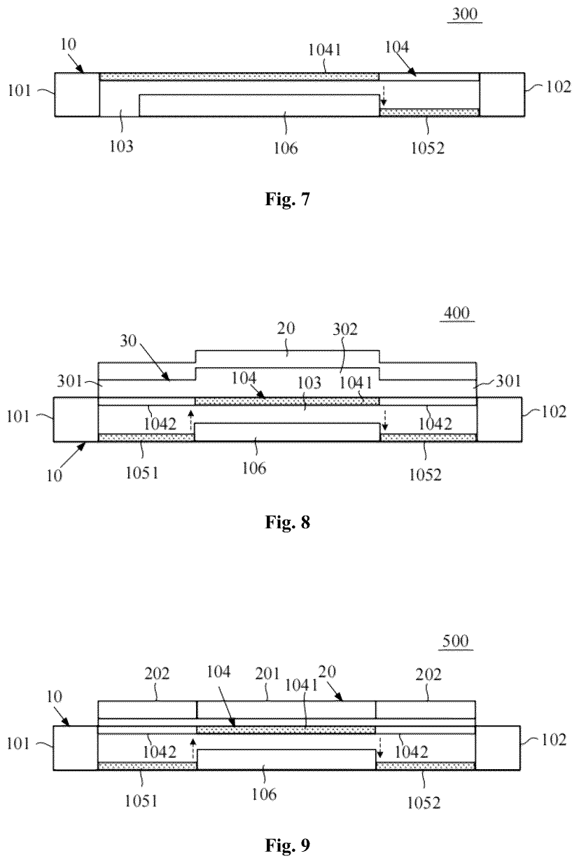

Referring to FIG. 7, yet another embodiment of a field-effect transistor device 300 of the present invention is described.

Unlike the embodiments described above, in the present embodiment, no equivalent source region is formed in the channel region 103 when the device is in an on-state. The field-effect transistor device 300 supplies a working current by connecting the source region 101 and the drain region 102 via an effective channel 1041 and an equivalent drain region 1052.

In the present embodiment, it is equivalent to only providing the equivalent drain region 1052 to reduce the influence of the drain potential on the effective channel 1041, thereby improving the short-channel effect of the device. Correspondingly, the effective channel 1041 is directly connected to the source region. When the device is in an on-state, during carrier transport process, carriers provided by the source region 101 enter the effective channel 1041. A portion of carriers are injected into the equivalent drain region 1052 from the end of the effective channel 1041 that is away from the source region 101 and back into the drain region 102. That is, in the present embodiment, only the effective channel 1041 injects carriers unidirectionally into the conductive region.

Correspondingly, in the present embodiment, the vertical projection of the equivalent drain region 1052 lies within the vertical projection of the carrier blocking region 106 in a plane perpendicular to the length direction of the effective channel 1041. In such an embodiment, since an equivalent source region is not provided, the carrier blocking region 106 corresponds to the shortest path for “blocking” the direct injection of carriers into the equivalent drain region 1052 in the source region 101, thereby also serving the function of reducing the off-state current of the device.

In the above embodiment, it can be seen that in order to provide the carrier blocking region 106 with a more desirable ability to reduce the off-state current of the device, the height of the carrier blocking region 106 may be as large as possible in the thickness direction of the effective channel 1041, and the height of the carrier blocking region 106 is limited so as not to affect the formation of the channel 104 when the device is in an on-state.

The structure in which a portion of a channel formed by gate control constitutes an effective channel has been shown in the above-described embodiment. In such a structure, to further improve the ability of the device to suppress short-channel effects, the effective channel in the channels may be arranged to have a conductance per unit length less than the conductance per unit length of the remainder of the channel excluding the effective channel. Some corresponding embodiments are described below.

Referring to FIG. 8, yet another embodiment of a field-effect transistor device 400 of the present invention is described.

The field-effect transistor device 400 includes an active layer 10 which comprises a source region 101, a drain region 102, and a channel region 103. The source region 101 and a drain region 102 are located on two sides of the active layer 10 respectively, and a channel region 103 is located between the source region 101 and the drain region 102.

An insulating layer 30 and a first gate electrode 20 are successively arranged above the channel region, and the thickness of the gate insulating layer 302 corresponding to the effective channel 1041 is greater than the thickness of the remainder of the gate insulating layer 301. That is, the gate insulating layer 301 of the corresponding portion of the equivalent source region 1051 and the equivalent drain region 1052 is relatively thinned, so that the modulation ability of the corresponding gate electrode of the rest portion of the channel 1042 except for the effective channel 1041 to the corresponding portion of the channel 1042 may be enhanced, thereby increasing the conductance of the corresponding portion of the channel 1042.

In the present embodiment, the dielectric constant of the gate insulating layer 302 corresponding to the effective channel 1041 may be set to be less than that of the remainder of the gate insulating layer 301, so as to further increase the conductance of the remainder of the channel 1042 except for the effective channel 1041.

Referring to FIG. 9, yet another embodiment of a field-effect transistor device 500 of the present invention is described.

The field-effect transistor device 500 includes an active layer 10 which comprises a source region 101, a drain region 102, and a channel region 103. A source region 101 and a drain region 102 are located on two sides of the active layer 10 respectively, and a channel region 103 is located between the source region 101 and the drain region 102.

A first gate electrode 20 is arranged above the channel region 103, and a portion 201 corresponding to the effective channel 1041 and a rest portion 202 of the first gate electrode 20 are made of different materials, so that the portion 201 of the first gate electrode 20 corresponding to the effective channel 201 and the remaining portion 202 have different modulation abilities for the channel formed correspondingly, and the conductance of the effective channel 1041 is realized to be greater than the conductance of the rest portion 1042 of the channel 104 except for the effective channel 1041. In the present embodiment, if the field-effect transistor device 500 is an N-type device, the work function of the portion 201 of the first gate electrode 20 corresponding to the effective channel 1041 is arranged to be greater than the work function of the remainder portion 202 of the first gate electrode 20; correspondingly, if the field-effect transistor device 500 is a P-type device, the work function of the portion 201 of the first gate electrode 20 corresponding to the effective channel 1041 is arranged to be less than the work function of the remainder portion 202 of the first gate electrode 20.

In particular, in the case of an N-type device, metals with a greater work function, such as gold, platinum, or P-type doped (P+) polysilicon, or ITO, RuO2, WN, MON, etc. with a greater work function obtained by adjusting the composition of the compound, may be used as a gate electrode material in the portion 201 of the first gate electrode 20 corresponding to the effective channel 1041; a metal with a less work function, such as aluminum, hafnium, titanium, or N-type doped (n+) polysilicon, or Ru-Hf, WN, HfN, TIN, TaN, TaSiN, etc. with a less work function obtained by adjusting the composition of the compound, may be used as a gate electrode material in the remainder portion 202. In the case of a P-type device, metals with a less work function, such as aluminium, hafnium, titanium, or N-type doped (n+) polysilicon, or Ru-Hf, WN, HfN, TiN, TaN and TaSiN, etc. with a less work function obtained by adjusting the composition of the compound, may be used as a gate electrode material in the portion 201 of the first gate electrode 20 corresponding to the effective channel 1041; a metal with a greater work function, such as gold, platinum, or P-type doped (P+) polysilicon, or ITO, RuO2, WN, MON, etc. with a greater work function obtained by adjusting the composition of the compound, may be used as a gate electrode material in the remainder portion 202.

The manner in which the conductive regions are formed in the present invention is described below in some specific examples:

### Embodiment 1

The conductive region is formed by doping the introduced carriers by the channel region 103A on a side surface away from the effective channel 1041A.

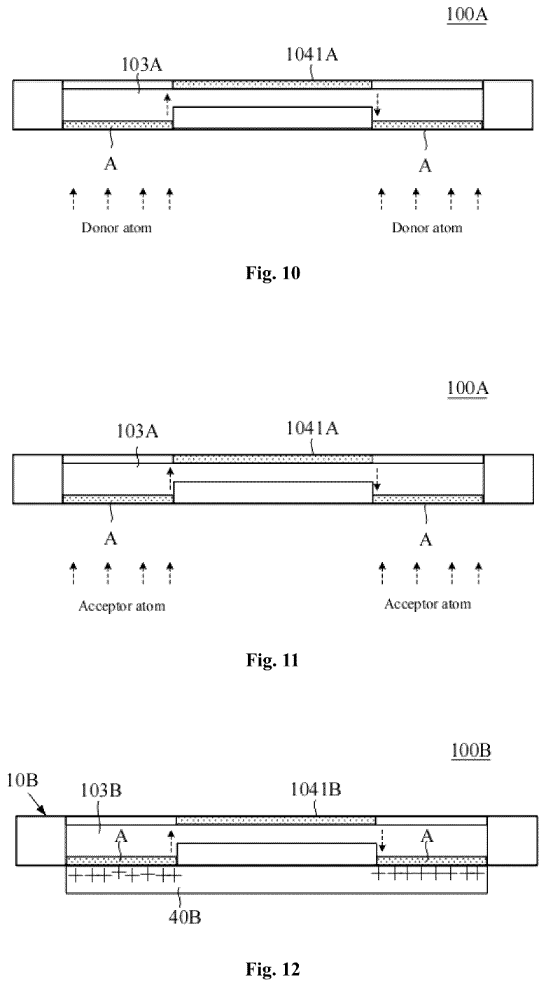

Correspondingly, referring to FIG. 10, in the case of an N-type silicon-based device 100A, the doping concentration at the interface may be varied by doping donor atoms, such as phosphorus, arsenic, etc. at the surface of the channel region 103A away from the effective channel 1041A. Referring to FIG. 9, in the case of a P-type silicon-based device 100A, the doping concentration at the interface may be varied by doping acceptor atoms, such as boron, at the surface of the channel region 103A away from the effective channel 1041A.

### Embodiment 2

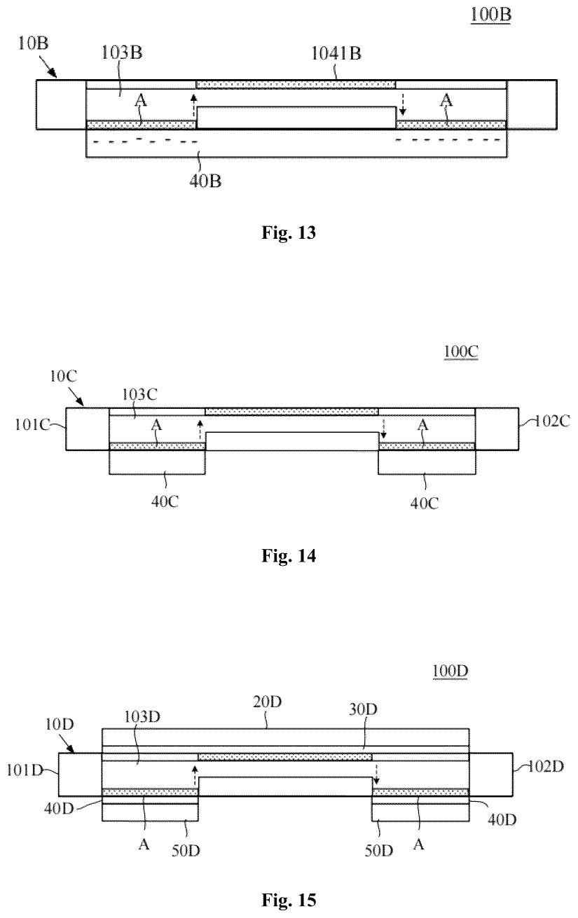

Referring to FIGS. 12 and 13, the field-effect transistor device 100B further includes an insulating layer 40B provided on a side surface of the active layer 10B away from the effective channel 1041B. The conductive region A is formed on a side surface of the channel region by electrostatic induction from injecting charges in the insulating layer 40B.

Correspondingly, referring to FIG. 12, in the case of an N-type device, this can be achieved by local injection of positive charges, e.g., H+, holes, in the insulating layer 40B. Referring to FIG. 13, in the case of a P-type device, this can be achieved by local injection of negative charges, such as F—, Cl—, electrons, etc. in the insulating layer 40B. In this manner, a high density of fixed charges is formed in the insulating layer 40B, and carriers of the conductive region A are generated adjacent to the insulating layer 40B in the channel region 103B by electrostatic induction. It should be noted that “local” herein refers to a portion of the insulating layer 40B corresponding to the portion of the channel region where the conductive region A is desired to be formed.

In a specific charge injection process, charges may be injected into the insulating layer 40B at a location closer to the channel region 103B to enable the conductive region A formed in the channel region 103B to store more carriers. In some other alternative embodiments, a “double insulating layer” structure may also be used, which specifically includes a charge-trapping layer provided on the surface of the channel region 103B, and a conventional insulating layer overlying the charge-trapping layer. The charge-trapping layer may be made of a material that is more likely to store charges, or nanoparticles of metal or semiconductor may be introduced therein to store charges more stably, thereby ensuring stable and controllable charge carriers in the conductive region.

### Embodiment 3

Referring to FIG. 14, the field-effect transistor device 100C includes a semiconductor material layer 40C provided on the active layer 10C. The semiconductor material layer 40C and the active layer 10C constitute a heterostructure, and the conductive region A is formed of a two-dimensional electron gas channel or a two-dimensional hole gas channel distributed in the heterostructure.

Specifically, the semiconductor material layer 40C and the active layer 10C have different band gap widths. The semiconductor material layer 40C can be divided into two portions connected to the source region 101C and the drain region 102C respectively, so that the formed two-dimensional electron gas channel does not conduct the source and drain regions.

Of course, in some alternative embodiments, a two-dimensional electron gas channel or a two-dimensional hole gas channel may also be formed, such as by surface treatment of the channel region 103C. Such alternative embodiments known to a person skilled in the art to form a two-dimensional electron gas channel or a two-dimensional hole gas channel are intended to be within the scope of the present invention. Furthermore, the semiconductor material layer 40C described herein may be a barrier layer which may be doped or intrinsic.

### Embodiment 4

Referring to FIG. 15, the field-effect transistor device 100D is fabricated as a device including at least two gate electrodes. Specifically, the field-effect transistor device 100D includes a first gate insulating layer 30D and a first gate electrode 20D sequentially provided on a side surface of the active layer 10D, and a second gate insulating layer 40D and a second gate electrode 50D sequentially provided on a side surface of the active layer 10D adjacent to the conductive region A.

The second gate electrode 50D is correspondingly divided into two portions, the vertical projection of one portion onto the active layer 10D is connected to the source region 101D, and the vertical projection of the other portion onto the active layer 10D is connected to the drain region 102D. As such, when an appropriate bias voltage is applied to the two portions of the second gate electrode 50D, two conductive regions A connecting with the source region 101D and the drain region 102D respectively can be formed at corresponding positions in the channel region 103D.

In this embodiment, the absolute value of the bias voltage applied to the second gate electrode 50D should be greater than the absolute value of the turn-on voltage applied to the device. Correspondingly, in the case of an N-type device, a positive bias voltage greater than that of the first gate electrode 20D is applied to the second gate electrode 50D; in the case of a P-type device, a negative bias voltage having an absolute value greater than that of the first gate electrode 20D is applied to the second gate electrode 50D.

### Embodiment 5

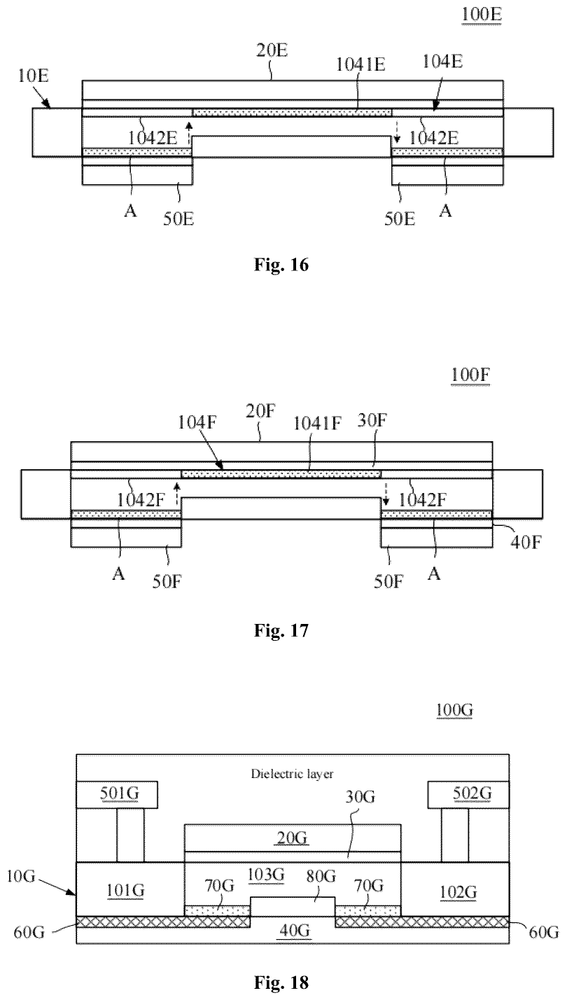

Referring to FIG. 16, the field-effect transistor device 100E is fabricated to include at least two gate electrodes similar to that of Embodiment 4. However, the difference is that in this embodiment, in order to enable the conductance of the conductive region A to be greater than the conductance of the portion 1042E of the channel 104E except for the effective channel 1041E, it is possible to use the first gate electrode 20E and the second gate electrode 50E of gate electrode materials with different work functions. That is to say: it may be achieved by a work function difference between the first gate electrode 20E and the active layer 10E that is not equal to the work function difference between the second gate electrode 50E and the active layer 10E.

Correspondingly, in the case of an N-type device, metals with a greater work function, such as gold, platinum, or P-type doped (P+) polysilicon, or ITO, RuO2, WN, MON, etc. with a greater work function obtained by adjusting the composition of the compound, may be used as a gate electrode material by the first gate electrode 20E; a metal with a less work function, such as aluminum, hafnium, titanium, or N-type doped (n+) polysilicon, or Ru-Hf, WN, HIN, TIN, TaN, TaSiN, etc. with a less work function obtained by adjusting the composition of the compound, may be used as a gate electrode material by the second gate electrode 50E. In the case of a P-type device, a metal with a less work function, such as aluminium, hafnium, titanium, or N-type doped (n+) polysilicon, or Ru-Hf, WN, HAN, TIN, TaN and TaSiN, etc. with a less work function obtained by adjusting the composition of the compound, may be used as a gate electrode material by the first gate electrode 20E; metals with a greater work function, such as gold, platinum, or P-type doped (P+) polysilicon, or ITO, RuO2, WN, MoN, etc. with a greater work function obtained by adjusting the composition of the compound, may be used as a gate electrode material by the second gate electrode 50E.

In an N-type device, the work function difference between the first gate electrode 20E and the active layer 10E may also be arranged to be greater than zero (Φms>0 V), so that the channel 104E is an enhanced channel: at the same time, the work function difference between the second gate electrode 50E and the active layer 10E is arranged to be less than zero (Φms<0 V), so that the conductive region A may also form a certain number of carriers under the bias voltage applied thereon when the device is in an off-state. In a P-type device, the work function difference between the first gate electrode 20E and the active layer may be arranged to be less than zero (Φms<0 V), so that the channel 104E is an enhanced channel: at the same time, the work function difference between the second gate electrode 50E and the active layer 10E is arranged to be greater than zero (Φms>0 V), so that the conductive region A may also form a certain number of carriers under the bias voltage applied thereon when the device is in an off-state.

### Embodiment 6

Referring to FIG. 17, the field-effect transistor device 100F is fabricated to include at least two gate electrodes 20F, 50F similar to that of Embodiment 4. However, the difference is that in this embodiment, in order to enable the conductance of the conductive region A to be greater than the conductance of the portion 1042F of the channel 104F except for the effective channel 1041F, the capacitance per unit area of the second gate insulating layer 40F may be arranged to be greater than the capacitance per unit area of the first gate insulating layer 30F.

In particular, this may be achieved by adjusting the dielectric constants of the first gate insulating layer 30F and the second gate insulating layer 40F, or the thicknesses of the first gate insulating layer 30F and the second gate insulating layer 40F.

For example, when the thicknesses of the first gate insulating layer 30F and the second gate insulating layer 40F are equal, the dielectric constant of the second gate insulating layer 40F may be arranged to be higher than the dielectric constant of the first gate insulating layer 30F only considering the dielectric constant of the gate insulating layer. Illustratively, the first gate insulating layer 30F may use silicon dioxide and the second gate insulating layer 40F may use dielectric with a high dielectric constant, such as hafnium dioxide, aluminum oxide, etc.

As another example, when the materials of the first gate insulating layer 30F and the second gate insulating layer 40F are the same, the thickness of the second gate insulating layer 40F may be arranged to be less than the thickness of the first gate insulating layer 30F only considering the thickness of the gate insulating layer. In particular device applications, the second gate electrode in embodiments 4-6 described above may also be directly floating or grounded, to avoid increasing the complexity of the device invention with excessive device connections.

Furthermore, the manner in which the conductive regions are formed in each of the above embodiments may be applied in combination with each other to achieve a better implementation effect.

The field-effect transistor device described in each of the above embodiments may be a planar structure device or a vertical structure device. In the following, a SOI device (TFT device) will be taken as an example to illustrate the specific arrangement of the solution of the present invention when applied to a SOI device.

### Embodiment 7

Referring to FIG. 18, it is a TFT device 100G with a planar top gate structure, and includes a light-transmitting insulating substrate 40G, and an active layer 10G, a gate dielectric layer 30G and a gate electrode 20G which are successively arranged on the substrate 40G. Two sides of the active layer 10G are respectively doped to form a source region 101G and a drain region 102G, and are respectively externally connected to a source electrode and a drain electrode; the channel region 103G is located between the source region 101G and the drain region 102G.

A positive charge region 60G is formed on both sides of the source region 101G and the drain region 102G by ion implantation or the like on the substrate 40G. The positive charge region 60G and the gate electrode 20G have an overlapping portion between the vertical projections of the channel region 103G, and correspondingly, the positive charge region of the overlapping portion may form a two-dimensional electron gas 70G in the channel region 103G which is respectively connected to the source region 101G and the drain region 102G. . . . The two-dimensional electron gas 70G also constitutes conductive region. The carrier blocking region 80G is formed between the two-dimensional electron gas 70G connected to the source region 101G and the drain region 102G.

When the device is on, a channel is formed below the gate electrode 20G, and the portion of the channel with a vertical projection located between the conductive regions constitutes the actual effective channel.

### Embodiment 8

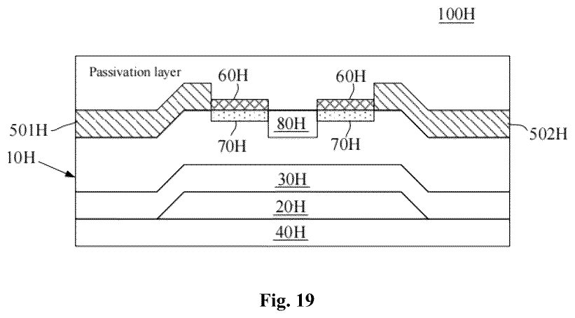

Referring to FIG. 19, it is a TFT device 100H with a planar bottom gate structure, and includes a light-transmitting insulating substrate 40H, and a gate electrode 20H, a gate dielectric layer 30H and an active layer 10H which are successively arranged on the substrate 40H. In the present embodiment, an upper metal source electrode 501H and a metal drain electrode 502H are respectively arranged on two sides of an active layer 10H, the active layer 10H may use an amorphous IGZO metal oxide semiconductor layer, and an ohmic contact is formed between the source electrode 501H and the drain electrode 502H and the active layer 10H. A portion of the active layer below the source electrode 501H and the drain electrode 502H constitutes a source region, a drain region respectively, and a channel region is thus located between the source region and the drain region.

The positive charge region 60H is formed by ion implantation in the passivation layer covered by the upper layer of the device, which is connected to the source electrode 501H and the drain electrode 502H. The positive charge region 60H and the gate electrode 20H have an overlapping portion between the vertical projections of the channel region, and correspondingly, the positive charge region of the overlapping portion may form a two-dimensional electron gas 70H in the channel region which is respectively connected to the source region and the drain region, and the two-dimensional electron gas 70H herein also constitutes a conductive region. The carrier blocking region 80H is formed between the two-dimensional electron gas 70H connected to the source region 101G and the drain region 102G.

When the device is on, a channel is formed above the gate electrode 20H, and the portion of the channel with a vertical projection located between the conductive region 70H constitutes the actual effective channel.

### Embodiment 9

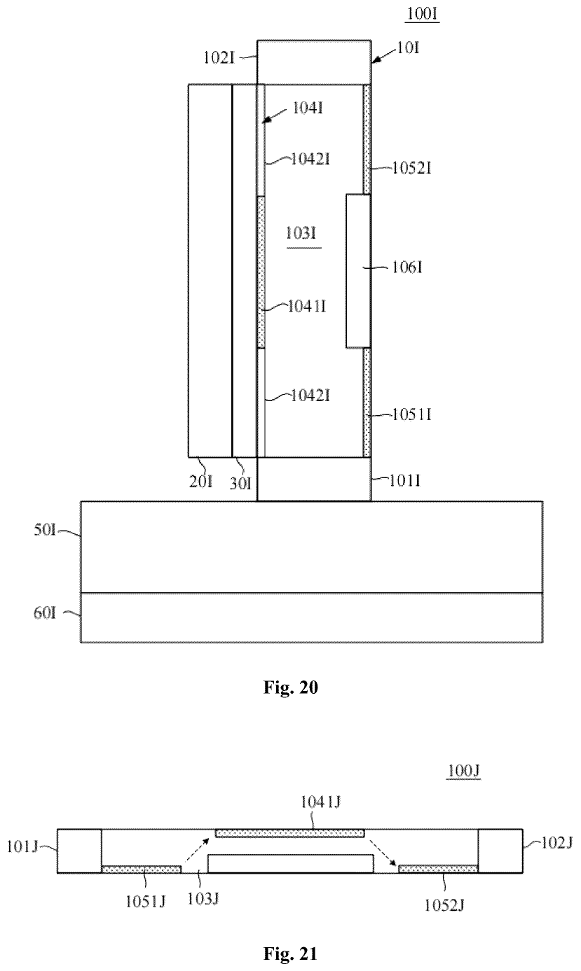

Referring to FIG. 20, it is a SOI device 100I with a vertical structure, and includes a substrate 60I, a buried insulating layer 50I and an active layer 10I successively arranged on the substrate 60I, a gate insulating layer 30I and a gate electrode 20I arranged on one side of the active layer 10I. The source region 101I and the drain region 102I are located below and above the active layer 10I, respectively, in a direction away from the substrate 60I. An equivalent source region 1051I in connection with the source region 101I, and an equivalent drain region 1052I in connection with the drain region 102I are formed in the channel region 103I. The carrier blocking region 106I is formed between the equivalent source region 1051I and the equivalent drain region 1052I.

When the device is on by applying a bias voltage to the gate electrode 20I of the device, the gate electrode 20I controls the formation of a channel 104I connecting the source region 101I and the drain region 102I in the channel region 103I of the device. However, only the portion of the channel 104I which the vertical projection on the channel region 103I does not overlap with the equivalent source region 1051I and the equivalent drain region 1052I constitutes an effective channel 1041I for transferring the working current when the device is on, i.e. the remaining portion 1042I in the channel 104I is not used for transferring the working current when the device is on.

In each of the above-mentioned embodiments, the source region and the drain region of the device may be a common heavily doped semiconductor source/drain, and may also be a Schottky metal source/drain of a metal-semiconductor structure; the gate electrode may be a common metal-insulator-semiconductor MOS structure, and may also be a Schottky junction gate electrode of a metal semiconductor structure; the active layer may be composed of a single semiconductor material or may also include at least two semiconductor materials varying in the direction of thickness or planar extension to form a composite channel.

In addition, the equivalent source region and the equivalent drain region may be formed spontaneously or may be controllably formed by the gate electrode with a corresponding structure.

In general, in the embodiments described above, the vertical projection of the effective channel, the equivalent source region and/or the equivalent drain region superimposed on the channel region facilitates communication between the source region and the drain region, thereby ensuring that the carriers of the effective channel and the equivalent source region and/or the equivalent drain region may be injected unidirectionally or bidirectionally at least in the thickness direction and constructing a carrier path from the source region to the drain region. Of course, referring to FIG. 21, the present invention does not exclude that in some particular embodiments, if the vertical projection of the effective channel, the equivalent source region and the equivalent drain region superimposed on the channel region 103J is not able to communicate the source region 101J and the drain region 102J of the device 100J, but has an “appropriate spacing”, the spacing is not able to completely cut off the path of the carriers flowing from the equivalent source region 1051J to the effective channel 1041J and from the effective channel 1041J to the equivalent drain region 1052J, the injection direction of the carriers between the effective channel 1041J, the equivalent source region 1051J and the equivalent drain region 1052J is at an angle to the thickness direction of the channel region 103J, and such an embodiment should also fall within the scope of protection of the present invention.

The following are the results of Silvaco TCAD simulation verification using the SOI device applying the above embodiments of the present invention.

### Simulation Embodiment 1

In Simulation embodiment 1, the SOI device to which the above-described implementations/embodiments of the present invention are applied is referred to as “SOI device of the present invention”. As a comparison, a SOI device having a structure similar to that of the SOI device of the present invention is distinguished only in that the carrier blocking region is not provided in the reference SOI device (referred to as a reference SOI device in the present simulation example), and the active region thickness of the reference SOI device is equal to that of the SOI device of the present invention.

Simulation parameters: the source and drain doping is N-type, the doping concentration is 1E21 cm⁻³, the channel doping is P-type, the doping concentration is 1E17 cm⁻³, the channel length L_{g} is 130 nm, the effective channel length L_{eff} is 70 nm, the lengths of the equivalent source region Lₑₛ and the equivalent drain region L_{ed} are both 30 nm, the thickness of the active layer is 50 nm, the thickness of the gate insulating layer is 5 nm, the area density of fixed charges at the interface where the equivalent source region and the equivalent drain region are formed is 1E14 cm⁻², the drain voltage V_{d}=2V, and the gate voltage V_{g}=2V.

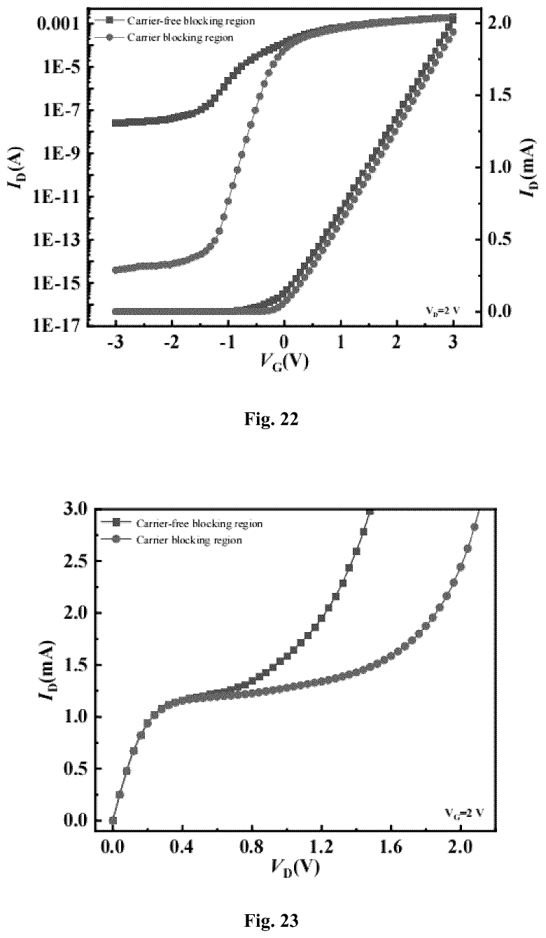

Referring to FIG. 22, it is a comparison diagram showing the transfer characteristics of the SOI device of the present invention and the reference SOI device when the drain voltage V_{d} is 2V. It can be seen that the off-state current of the SOI device of the present invention is significantly improved, and the sub-threshold swing of the SOI device of the present invention is 110 mV/dec. Compared with the sub-threshold swing of the reference SOI device of 287 mV/dec, it is shown that the gating capability is improved.

Referring to FIG. 23, it is a comparison diagram showing the output characteristics of the SOI device of the present invention and the reference SOI device when the gate voltage V_{g} is 2V. It can be seen that the output characteristic curve of the SOI device of the present invention is flatter and the operating range is wider, and the kink voltage is 0.66V which is significantly improved compared with the kink voltage of 0.78V of the reference SOI device, which effectively reduces the carrier impact ionization effect when the device is in operation. The kink current is suppressed and the output characteristic of the device is enhanced. Further, the kink voltage and the output impedance Rₒ of the SOI device of the present invention are significantly improved based on relatively little loss of the saturation voltage V_{dsat} and the saturation current I_{dsat} (6.81 kω for the SOI device of the present invention, and 2.99 kω for the reference SOI device).

### Simulation Embodiment 2

In Simulation embodiment 2, the SOI device to which the above-described implementations/embodiments of the present invention are applied is referred to as “SOI device of the present invention”.

Simulation parameters: the source and drain doping is N-type, the doping concentration is 1E21 cm⁻³, the channel doping is P-type, the doping concentration is 1E17 cm⁻³, the channel length L_{g} is 130 nm, the effective channel length L_{eff} is 70 nm, the lengths of the equivalent source region Lₑₛ and the equivalent drain region Led are both 30 nm, the thickness of the active layer is 50 nm, the thickness of the gate insulating layer is 5 nm, the area density of fixed charges at the interface where the equivalent source region and the equivalent drain region are formed is 1E14 cm⁻², the drain voltage V_{d}=2V, and the gate voltage V_{g}=2V, and the carrier blocking region height in the channel thickness direction is 10 nm, 25 nm and 40 nm, respectively.

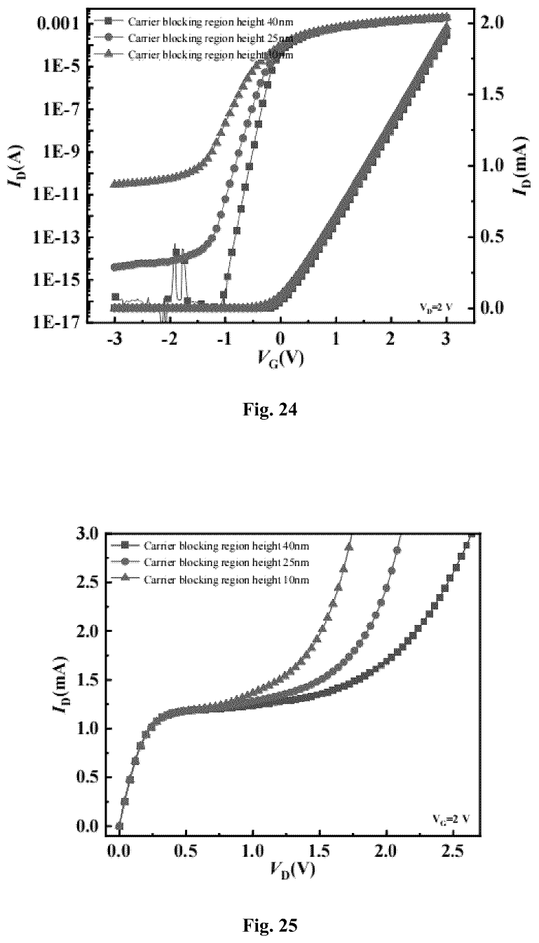

Referring to FIG. 24, it is a comparison diagram showing the transfer characteristics of the SOI device of the present invention at different heights of carrier blocking region with a drain voltage V_{d} of 2V. It can be seen that the sub-threshold swing of the SOI device of the present invention is 174 mV/dec, 110 mV/dec and 79 mV/dec respectively when the carrier blocking height is 10 nm, 25 nm, and 40 nm respectively, that is to say, the higher the carrier blocking region is, the smaller the sub-threshold swing is. The gate control capability is improved, and the off-state current is lower.

Referring to FIG. 25, it is a comparison diagram showing the output characteristics of the SOI device of the present invention when the carrier blocking region height is different and the gate voltage V_{g} is 2V. It can be seen that the higher the carrier blocking region, the flatter the output characteristic curve and the wider the operating range of the SOI device of the present invention. When the carrier blocking region height is 10 nm, 25 nm and 40 nm, the kink voltages of the SOI device of the present invention are 0.66V, 0.78V and 0.84V respectively, that is to say, the higher the carrier blocking region is, the more the kink current is effectively suppressed, and the output characteristics of the device are improved. Meanwhile, the higher the carrier blocking region, the better the output impedance Rₒ can be obtained without loss of saturation voltage V_{dsat} and saturation current I_{dsat}. When the carrier blocking region height is 10 nm, 25 nm, and 40 nm, the output impedance Rₒ is 5.07 kΩ, 6.53 kΩ and 11.57 kΩ respectively.

### Simulation Embodiment 3

In Simulation embodiment 3, the SOI device to which the above-described implementations/embodiments of the present invention are applied is referred to as “SOI device of the present invention”.

Simulation parameters: the source and drain doping is N-type, the doping concentration is 1E21 cm⁻³, the channel doping is P-type, the doping concentration is 1E17 cm⁻³, the channel length L_{g} is 130 nm, the effective channel length L_{eff} is 70 nm, the lengths of the equivalent source region Lₑₛ and the equivalent drain region Led are both 30 nm, the thickness of the active layer is 50 nm, the thickness of the gate insulating layer is 5 nm, the area density of fixed charges at the interface where the equivalent source region and the equivalent drain region are formed is 1E14 cm⁻², the drain voltage V_{d}=2V, and the gate voltage V_{g}=2 V, and the carrier blocking region respectively uses an oxide with a dielectric constant of 3.9 and Si₃N₄ with a dielectric constant of 7.5.

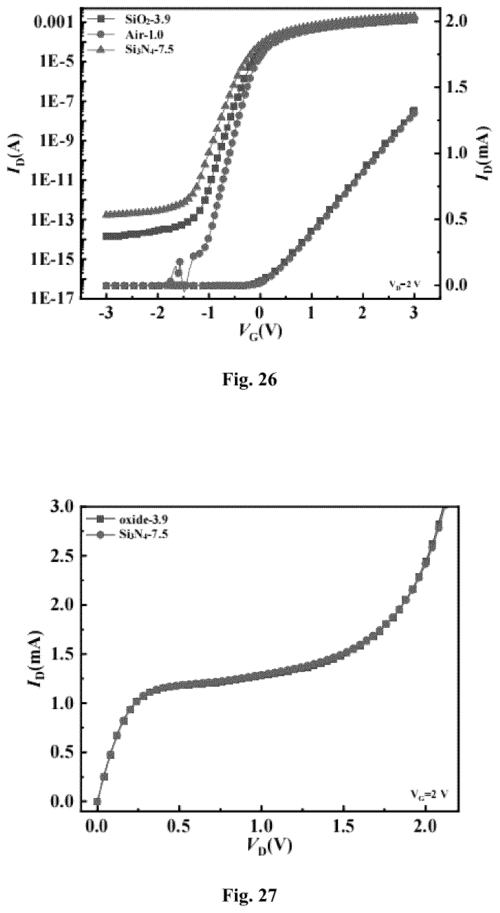

Referring to FIG. 26, a comparison graph of the transfer characteristics of the SOI device of the present invention at different dielectric constants of the carrier blocking region and a drain voltage V_{d} of 2V is shown. It can be seen that the lower the dielectric constant of the carrier blocking region is, the lower the off-state current of the SOI device of the present invention is, and the sub-threshold swing also shows that the gate control capability is improved, where the sub-threshold swing of the SOI device of the present invention using the carrier blocking regions of which the materials are Si₃N₄, SiO₂ and air is 131 mV/dec, 110 mV/dec and 79 mV/dec, respectively.

Referring to FIG. 27, it is a comparison diagram showing the output characteristics of the SOI device of the present invention in different dielectric constants of the carrier blocking region and when the gate voltage V_{g} is 2 V. It can be seen that the saturation voltage V_{dsat}, the saturation current I_{dsat}, the kink voltage and the output impedance Rₒ of the SOI device of the present invention are not greatly correlated with the change in the dielectric constant of the carrier blocking region.

### Simulation Embodiment 4

In Simulation embodiment 4, the SOI device to which the above-described implementations/embodiments of the present invention are applied is referred to as “SOI device of the present invention”. As a comparison, a SOI device having a structure like that of the SOI device of the present invention is distinguished only in that the carrier blocking region is not provided in the reference SOI device (referred to as a reference SOI device in the present simulation example), and the thickness of the active region of the reference SOI device is equal to the thickness of the active region minus the height of the carrier blocking region in the SOI device of the present invention.

Simulation parameters: the source and drain doping is N-type, the doping concentration is 1E21 cm⁻³, the channel doping is P-type, the doping concentration is 1E17 cm⁻³, the channel length L_{g} is 130 nm, the effective channel length L_{eff} is 70 nm, the lengths of the equivalent source region Lₑₛ and the equivalent drain region L_{ed} are both 30 nm, the thickness of the active layer is 50 nm, the thickness of the gate insulating layer is 5 nm, the area density of fixed charges at the interface where the equivalent source region and the equivalent drain region are formed is 1E14 cm⁻², the drain voltage is V_{d}=2V, and the gate voltage is V_{g}=2V.

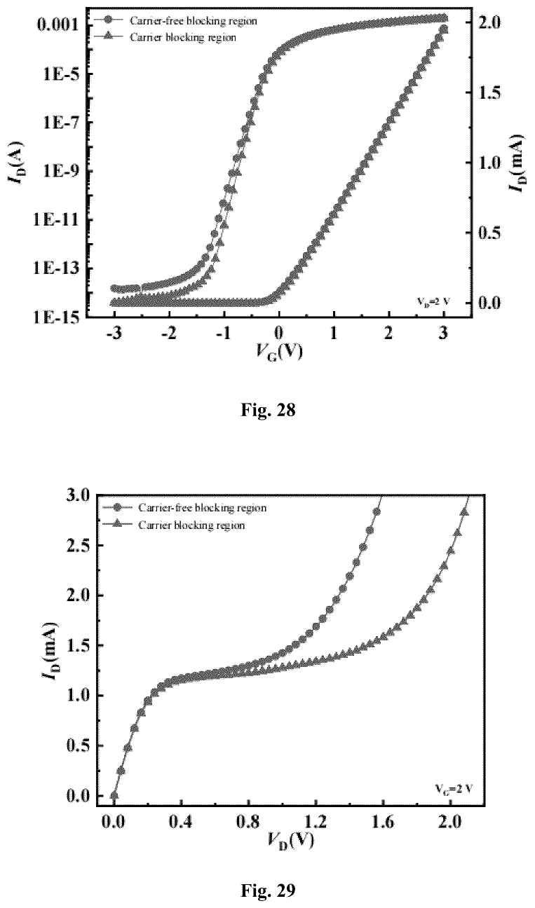

Referring to FIG. 28, it is a comparison diagram showing the transfer characteristics of the SOI device of the present invention and the reference SOI device when the drain voltage V_{d} is 2V. It can be seen that the sub-threshold swing of the SOI device of the present invention is 110 mV/dec, and compared with the sub-threshold swing of the reference SOI device being 128 mV/dec, In each of the above-mentioned embodiments, off-state current of the SOI device of the present invention is still relatively improved. Referring to FIG. 29, it is a comparison diagram showing the output characteristics of the SOI device of the present invention and the reference SOI device when the gate voltage V_{g} is 2V. It can be seen that the output characteristic curve of the SOI device of the present invention is flatter and the operating range is wider; the kink voltage (0.78V) and the output impedance Rₒ (6.65kω) of the SOI device of the present invention are improved with little loss of the saturation voltage V_{dsat} and the saturation current I_{dsat} relative to the kink voltage (0.64V) and the output impedance Rₒ (3.81ω) of the reference SOI device.

### Simulation Embodiment 5

In Simulation embodiment 5, the SOI device to which the above-described implementations/embodiments of the present invention are applied is referred to as “SOI device of the present invention”.

Simulation parameters: the source and drain doping is N-type, the doping concentration is 1E21 cm⁻³, the channel doping is P-type, the doping concentration is 1E17 cm⁻³, the channel length L_{g} is 130 nm, the effective channel length L_{eff} is 70 nm, the lengths of the equivalent source region Lₑₛ and the equivalent drain region L_{ed} are both 30 nm, the thickness of the active layer is 50 nm, the thickness of the gate insulating layer is 5 nm, the area density of fixed charges at the interface where the equivalent source region and the equivalent drain region are formed is 1E14 cm⁻², the drain voltage is V_{d}=2V, and the gate voltage is V_{g}=2V, and the widths of the carrier blocking regions in the direction of the effective channel length are 10 nm, 30 nm, 50 nm and 70 nm, respectively.

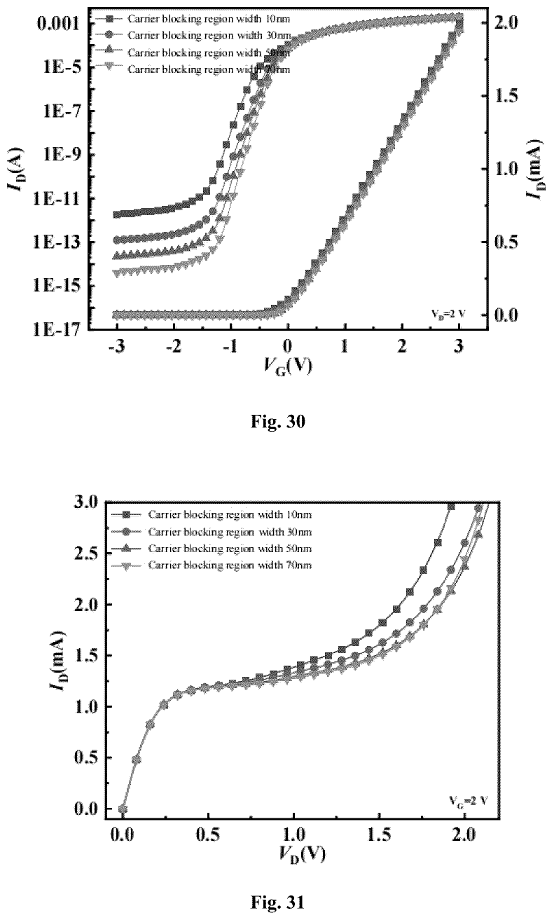

Referring to FIG. 30, a comparison graph of the transfer characteristics of the SOI device of the present invention at different dielectric constants of the carrier blocking region and a drain voltage V_{d} of 2V is shown. It can be seen that the larger the width of the carrier blocking region is, the smaller the off-state current of the SOI device of the present invention is. As for the sub-threshold swing, the SOI devices of the present invention with the carrier blocking region widths of 10 nm, 30 nm, 50 nm, and 70 nm, are 132 mV/dec, 127 mV/dec, 118 mV/dec and 110 mV/dec, respectively, which also shows that the gate control capability is improved as the width of the carrier blocking region becomes wider.

Referring to FIG. 31, it is a comparison diagram showing the output characteristics of the SOI device of the present invention in different dielectric constants of the carrier blocking region and the gate voltage V_{g} is 2V. It can be seen that when the carrier blocking region of the SOI device in the present invention is widened, the output characteristic curve is flatter and the operating range is wider. The kink voltages at 10 nm, 30 nm, 50 nm and 70 nm are 0.70 V, 0.74 V, 0.78 V and 0.77 V, respectively, and the kink current suppression ability is improved obviously. In terms of the output impedance Rₒ , the carrier blocking regions are 3.69 kω, 4.89 kω, 6.13 kω and 6.76 kω at 10 nm, 30 nm, 50 nm and 70 nm, respectively. That is to say, the wider the carrier blocking region is, the better the output impedance Rₒ is, and the saturation voltage V_{dsat} and saturation current I_{dsat} are hardly lost.

It should be understood that the described embodiments of the present invention are for illustrative purposes only and are not intended to limit the scope of the present invention, and that various other substitutions, alterations, and modifications may be made by a person skilled in the art within the scope of the present invention, and thus, the present invention is not limited to the above-described embodiments but only by the claims.

1. A field-effect transistor device having a blocking region, comprising an active layer, wherein the active layer includes a source region, a drain region, and a channel region located between the source region and the drain region;
wherein when the device is in an on-state, an effective channel and/or an equivalent source region and an equivalent drain region that are away from the effective channel, are formed in the channel region at least in a thickness direction of the channel region;
wherein the field-effect transistor device supplies a working current by connecting the source region and the drain region by means of the effective channel, and the equivalent source region and/or the equivalent drain region; and
the field-effect transistor comprises a carrier blocking region, and in a plane perpendicular to the length direction of the effective channel, vertical projections of the equivalent source region and of the equivalent drain region are located in a vertical projection of the carrier blocking region.

2. The field-effect transistor device having a blocking region according to claim 1, wherein a conductive region without connecting the source region and the drain region is formed in the channel region;
wherein when the conductive region is connected with the source region, the conductive region constitutes the equivalent source region; and/or,
when the conductive region is connected with the drain region, the conductive region constitutes the equivalent drain region.

3. The field-effect transistor device having a blocking region according to claim 2, comprising a first gate electrode arranged on a side surface of the active layer, a vertical projection of the first gate electrode on the channel region overlaping a vertical projection of the conductive region on the channel region; wherein the first gate electrode is capable of controlling the channel region and forming a channel therein, and a portion of the channel that does not overlap with the vertical projection of the conductive region on the channel region constitutes the effective channel.

4. The field-effect transistor device having a blocking region according to claim 3, wherein when the device is in an on-state, a conductance of the conductive region is greater than a conductance of a remainder of the channel excluding the effective channel, so that at least one of the conductive region and the effective channel is capable of injecting carriers into the other.

5. The field-effect transistor device having a blocking region according to claim 3, wherein when the device is in an on-state, a conductance per unit length of the effective channel in the channels is less than a conductance per unit length of a remainder of the channel excluding the effective channel.

6. The field-effect transistor device having a blocking region according to claim 3, further comprising a gate insulating layer arranged between the first gate electrode and a channel region, wherein a thickness of a portion of the gate insulating layer corresponding to the effective channel is greater than that of a remainder of the gate insulating layer; and
the field-effect transistor device comprises a gate insulating layer arranged between the first gate electrode and a channel region, wherein a dielectric constant of a portion of the gate insulating layer corresponding to the effective channel is greater than that of the remainder of the gate insulating layer.

7. The field-effect transistor having a blocking region according to claim 1, wherein a contact interface of the carrier blocking region and the channel region forms a potential energy barrier for preventing carriers from entering the carrier blocking region.

8. The field-effect transistor device having a blocking region according to claim 1, wherein vertical projections of the carrier blocking region and the equivalent source region and/or the equivalent drain region on the channel region do not overlap.

9. The field-effect transistor device having a blocking region according to claim 1, wherein the carrier blocking region is a dielectric material filled in a trench of the channel region; or,
the carrier blocking region is an insulating region or a semi-insulating region formed by ion implantation or doping in the channel region; or,
the carrier blocking region is a dielectric material formed on a substrate, and the active layer is prepared on the substrate on which the dielectric material is formed.

10. The field-effect transistor device having a blocking region according to claim 2, further comprising a second gate electrode arranged on a side surface of the active layer adjacent to the conductive region, the second gate electrode being capable of controlling the formation of the conductive region in the channel region.

11. The field-effect transistor device having a blocking region according to claim 3, wherein when the field-effect transistor device is an N-type device, a work function of a portion of the first gate electrode corresponding to the effective channel is greater than a work function of the remainder of the first gate electrode; and
when the field-effect transistor device is a P-type device, a work function of a portion of the first gate electrode corresponding to the effective channel is less than a work function of the remainder of the first gate electrode.

12. The field-effect transistor having a blocking region according to claim 1, wherein the carrier blocking region is an insulating region or a semi-insulating region; and
the dielectric constant of the carrier blocking region is less than the dielectric constant of the channel region.

13. The field-effect transistor device having a blocking region according to claim 1, wherein
the carrier blocking region is in contact with one terminal of the equivalent source region away from the source region; and
the carrier blocking region is in contact with one terminal of the equivalent drain region away from the drain region.

14. The field-effect transistor device having a blocking region according to claim 2, wherein the conductive region is formed by doping the introduced carriers by the channel region on a side surface away from the effective channel.

15. The field-effect transistor device having a blocking region according to claim 2, further comprising an insulating layer provided on a surface of the active layer on a side away from the effective channel, wherein the conductive region is composed of carriers generated in the channel region adjacent to the insulating layer by the injected charges in the insulating layer through electrostatic induction.

16. The field-effect transistor device having a blocking region according to claim 2, further comprising a semiconductor material layer provided on a side surface of the active layer away from the effective channel, wherein the active layer and the semiconductor material layer form a heterostructure, the conductive region is constituted by a two-dimensional electron gas channel or a two-dimensional hole gas channel distributed in the heterostructure.

17. The field-effect transistor device having a blocking region according to claim 2, wherein the conductive region is constituted by a two-dimensional electron gas channel or a two-dimensional hole gas channel formed by surface treatment of a side surface of the channel region away from the effective channel; and
the field-effect transistor device is a planar structure device or a vertical structure device.
